(19) United States
(12) Patent Application Publication
(10) Pub. No.: US 2020/0161440 A1
(43) Pub. Date: May 21, 2020

(54) METAL TO SOURCE/DRAIN CONTACT AREA USING THIN NUCLEATION LAYER AND SACRIFICIAL EPITAXIAL FILM

(71) Applicant: Intel Corporation, Santa Clara, CA (US)

(72) Inventors: Ritesh Jhaveri, Hillsboro, OR (US); Pratik A. Patel, Portland, OR (US); Ralph T. Troeger, Portland, OR (US); Szuya S. Liao, Portland, OR (US); Karthik Jambunathan, Hillsboro, OR (US); Scott J. Maddox, Hillsboro, OR (US); Kai Loon Cheong, Beaverton, OR (US); Anand S. Murthy, Portland, OR (US)

(73) Assignee: Intel Corporation, Santa Clara, CA (US)

(21) Appl. No.: 16/615,111

(22) PCT Filed: Jun. 30, 2017
(86) PCT No.: PCT/US2017/040262

§ 371 Date: Nov. 19, 2019

(51) Int. Cl. H01L 29/417; H01L 29/08; H01L 29/45; H01L 29/78; H01L 21/285; H01L 29/66

(52) U.S. Cl. CPC H01L 29/41791; H01L 29/0847; H01L 29/6681; H01L 29/7851; H01L 21/28518; H01L 29/45

(57) ABSTRACT

An apparatus is provided which comprises: a semiconductor region on a substrate, a gate stack on the semiconductor region, a source region comprising doped semiconductor material on the substrate adjacent a first side of the semiconductor region, a drain region comprising doped semiconductor material on the substrate adjacent a second side of the semiconductor region, a substantially conformal semiconductor layer over a surface of a recess in the source region, and a metal over the conformal layer substantially filling the recess in the source region. Other embodiments are also disclosed and claimed.

### BACKGROUND

In semiconductor devices, as transistor dimensions scale, the area forming the contact between a metal and the source/drain epitaxial region gets smaller and the contact resistance goes up. Contact resistance, as opposed to the intrinsic resistance of a material, refers to the resistance attributable to electricity flowing over an interface between materials, such as between metal and silicide, for example. Contact resistance increases power consumption and therefore heat which must managed.

The excess power consumption attributable to contact resistance can be one of the main factors limiting increased computer processor performance. Some efforts to minimize contact resistance include the use of specific metals and doped silicides in the source/drain regions, however the contact resistance will continue to increase in inverse proportion to the contact area.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a perspective view of an example semiconductor device with an enhanced metal contact area, according to some embodiments,

FIGS. 2A-2H illustrate cross-sectional views of manufacturing steps of a semiconductor device with an enhanced metal contact area, according to some embodiments,

FIG. 3 illustrates a cross-sectional view of another example semiconductor device with an enhanced metal contact area, according to some embodiments,

FIG. 4 illustrates a flowchart of a method of forming a semiconductor device with an enhanced metal contact area, in accordance with some embodiments, and

FIG. 5 illustrates a smart device or a computer system or a SoC (System-on-Chip) which includes a semiconductor device with an enhanced metal contact area, according to some embodiments.

### DETAILED DESCRIPTION

An enhanced metal contact area to lower metal to source/drain region contact resistance is generally presented. In this regard, embodiments of the present invention enable increased contact area by creating a recess through a source/drain region surface. The recess surface may be covered by a conformal nucleation layer that may be protected by a sacrificial layer before a metal interface is formed. One skilled in the art would appreciate that this approach may enable smaller transistor features without an associated increase in contact resistance.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” “right,” “front,” “back,” “top,” “bottom,” “over,” “under,” and the like in the description and in the claims, if any, are used for descriptive purposes and not necessarily for describing permanent relative positions.

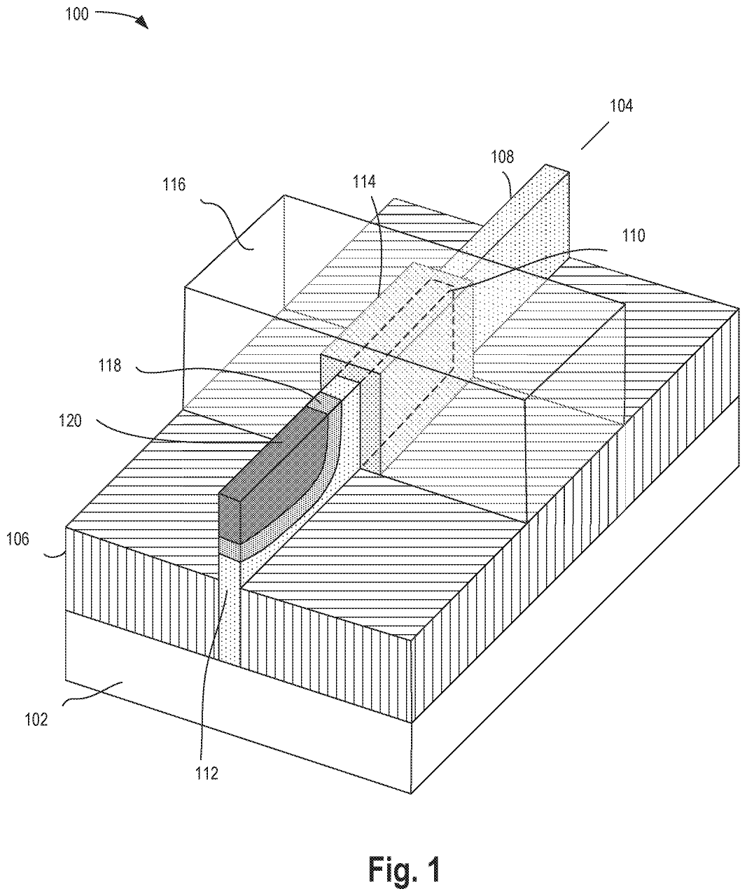

FIG. 1 illustrates a perspective view of an example semiconductor device with an enhanced metal contact area, according to some embodiments. As shown, device 100 includes substrate 102, fin 104, insulator 106, drain region 108, semiconductor region 110, source region 112, gate dielectric 114, gate region 116, nucleation layer 118, and contact metal 120. While shown as being a FinFET transistor, in other embodiments, device 100 may be a different topology, such as a planar transistor, or different device, such as a diode. While shown as including a single fin 104 and gate region 116, in some embodiments, device 100 may include multiple fins 104 and/or gate regions 116.

In some embodiments, substrate 102 comprises at least one layer of undoped semiconductor, such as Ge, Si, SiGe, InGaAs, AlSb, etc., which may form fin 104. In some embodiments, fin 104, which may include drain region 108, semiconductor region 110, and source region 112, may be formed separately from substrate 102 and may contain different semiconductor materials. Substrate 102 may be composed of one or more semiconductor material layers on top of another semiconductor material such as silicon. In some embodiments, insulator 106 is composed of a buried oxide layer that is adjacent to fin 104. When device 100 is in an active mode, semiconductor region 110 may serve as a channel between source region 112 and drain region 108, located on opposite sides of semiconductor region 110. In some embodiments, device 100 may be an NMOS transistor and source region 112 and drain region 108 are n-doped variants of the same semiconductor as semiconductor region 110, for example germanium.

Nucleation layer 118 may represent a substantially conformal thin film epitaxially formed on a surface of a recess created within source region 112. In some embodiments, nucleation layer 118 may comprise silicon or another semiconductor material. In some embodiments, nucleation layer 118 may include dopants, such as phosphorus or arsenic or similar molecules, for improved contact properties. While shown as being present in source region 112, nucleation layer 118 may also cover a surface of a recess formed in drain region 108. Contact metal 120 may contact nucleation layer 118 and fill the recess formed in source region 112. In some embodiments, contact metal 120 may comprise titanium, cobalt or other metals. One skilled in the art would appreciate the nucleation layer 118 provides a greater surface area to interface with contact metal 120 than would an upper surface of drain 108, for example. While shown as being curved in shape, in some embodiments nucleation layer 118 may include one or more planar surfaces.

Gate region 116, along with gate dielectric 114, may form a gate stack on semiconductor region 110. Gate region 116 may be a metal coupled with interconnects, not shown, to provide a voltage proximate to semiconductor region 110 to place device 100 into an active mode. In some embodiments, gate dielectric 114 may include oxides and/or nitrides.

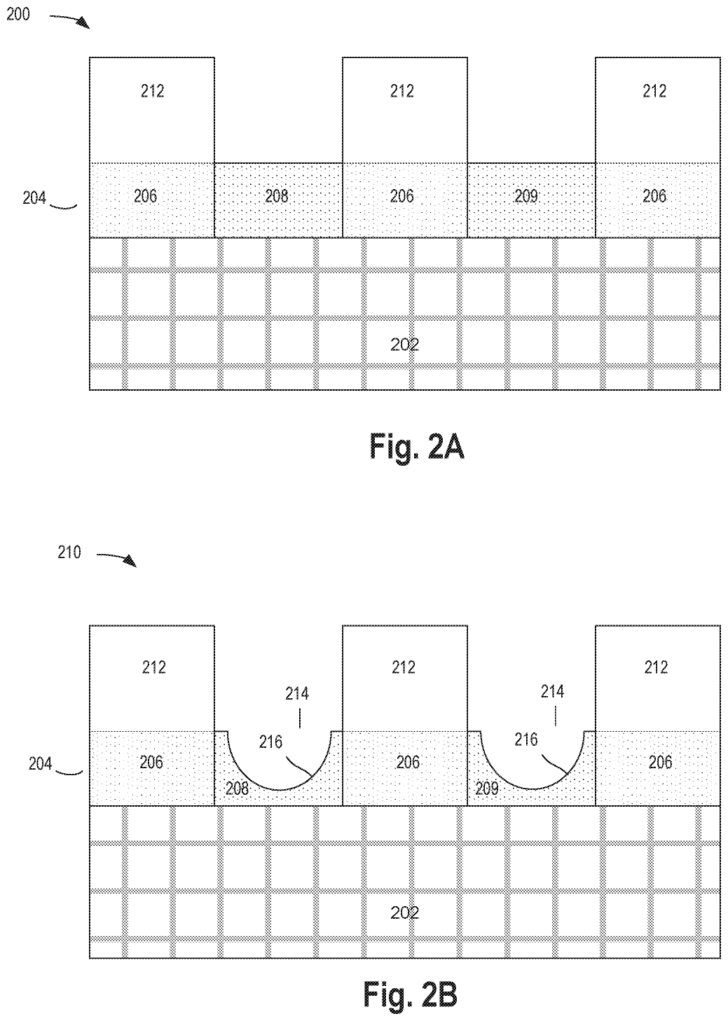

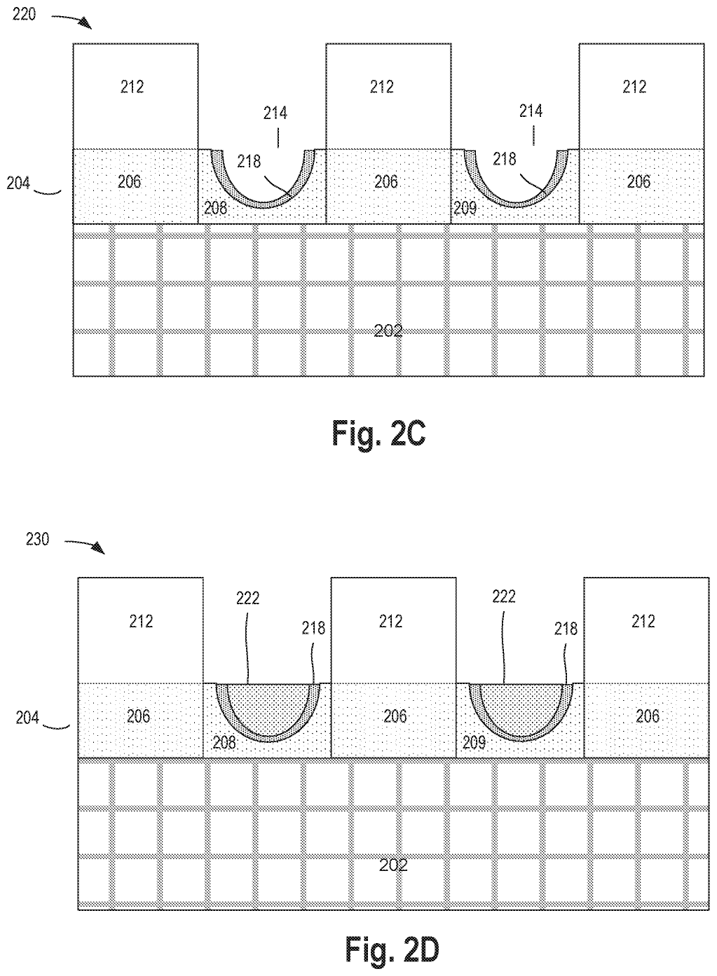

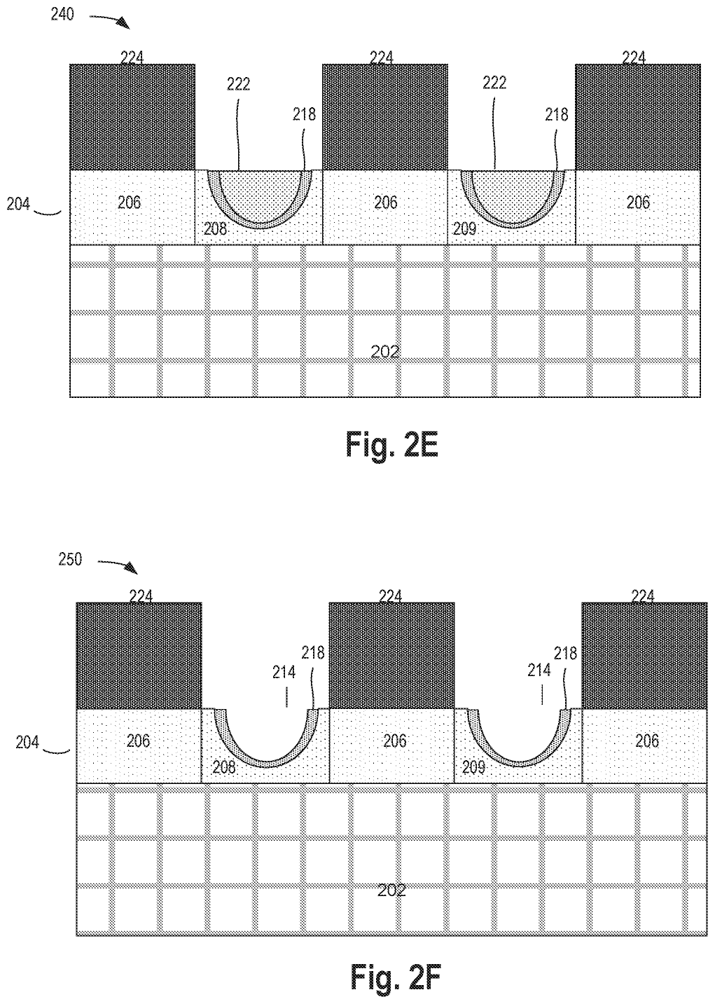

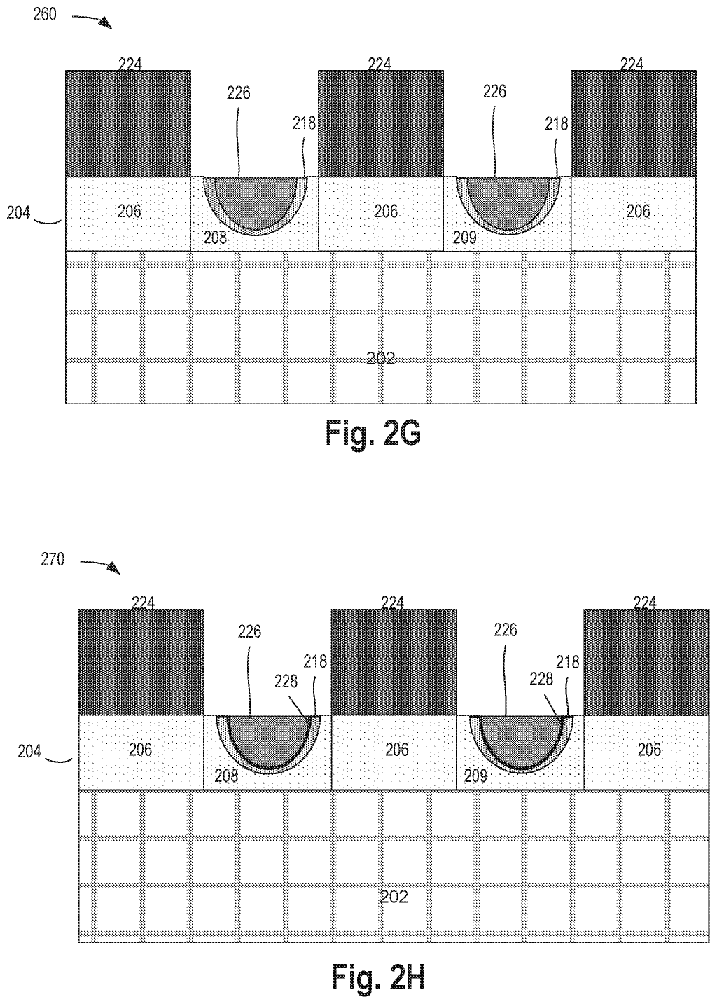

FIGS. 2A-2H illustrate cross-sectional views of manufacturing steps of a semiconductor device with an enhanced metal contact area, according to some embodiments. As shown in FIG. 2A, assembly 200 includes substrate 202, fin 204, semiconductor regions 206, source region 208, drain region 209, and gate regions 212. In some embodiments, assembly 200 represents a cross-section of a tri-gate FinFET, however in other embodiments different semiconductor devices may be used. For example, while shown as including fin 204, in some embodiments assembly 200 may be a planar transistor. Also, assembly 200 may include additional layers not shown.

FIG. 2B shows assembly 210, which may include recesses 214 formed in source region 208 and drain region 209, creating recess surfaces 216. In some embodiments, recesses 214 may be formed through chemical and/or mechanical processes including, but not limited to, chemical etching or laser ablation. Recess surfaces 216 may be smooth or rough, uniform or uneven. For example, in some embodiments recess surfaces 216 may slope up or down in z-dimension. While shown as being curved, recess surfaces 216 may include planar surfaces.

As shown in FIG. 2C, assembly 220 may have had nucleation layers 218 formed on recess surfaces 216. In some embodiments, nucleation layers 218 comprise silicon, however other semiconductor materials including, but not limited to, Ge, SiGe, InGaAs, AlSb may be used. In some embodiments, nucleation layers 218 may include dopants, such as phosphorus or arsenic, for example, either as part of a combined atomic deposition or as part of a separate implantation. In some embodiments, nucleation layers 218 are substantially conformal in depth, with thickness of about 5 nm or less. In some embodiments, nucleation layers 218 are epitaxially formed

Turning now to FIG. 2D, assembly 230 may include sacrificial material 222 covering nucleation layers 218 and filling recesses 214. In some embodiments, sacrificial material 222 comprises SiGe or Ge or some other material different than nucleation layers 218 that can later be removed through selective etching. In some embodiments, sacrificial material 222 is epitaxially formed.

FIG. 2E shows assembly 240, which may include formation of gate stacks 224. In some embodiments, gate regions 212 are subjected to processing steps to form gate stacks 224. In some embodiments, gate stacks 224 are formed through a gate replacement process to form separate spacer and metal regions (not shown). In some embodiments, the formation of gate stacks 224 may include processes that might otherwise result in damage to nucleation layers 218, if sacrificial material 222 did not cover them.

As shown in FIG. 2F, for assembly 250 sacrificial material 222 has been removed to once again expose nucleation layers 218 and recesses 214. In some embodiments, a selective etch, such as an isotropic chemical vapor etch, is used to remove sacrificial material 222 without removing nucleation layers 218.

Turning now to FIG. 2G, assembly 260 may include contact metal 226 formed on nucleation layers 218 and filling recesses 214. In some embodiments, contact metal 226 may be titanium, cobalt or other metals, including alloys.

FIG. 2H shows assembly 270, which may include silicide layers 228 formed between nucleation layers 218 and contact metal 226. In some embodiments, silicidation processes such annealing or sintering may form a metal-silicon alloy at the junction of nucleation layers 218 and contact metal 226. In some embodiments, silicide layers 228 may comprise a titanium silicon alloy, which has a significantly lower resistivity than a polysilicon.

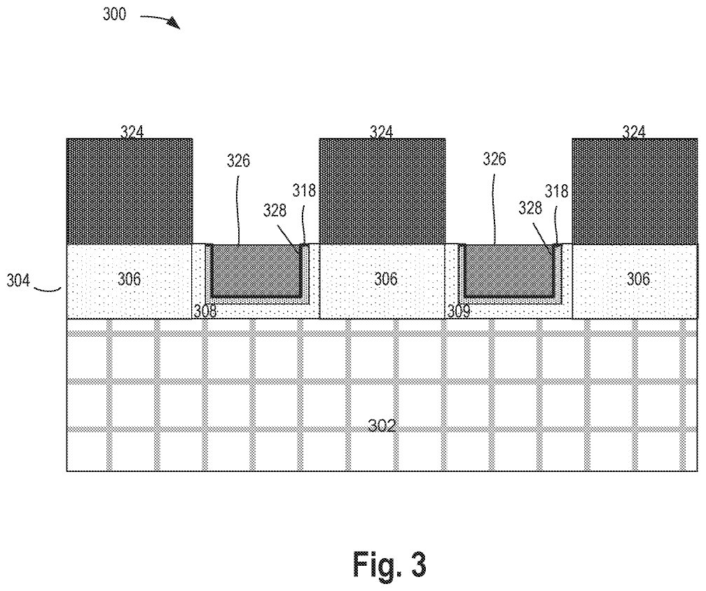

FIG. 3 illustrates a cross-sectional view of another example semiconductor device with an enhanced metal contact area, according to some embodiments. As shown, device 300 includes substrate 302, fin 304, semiconductor regions 306, source region 308, drain region 309, nucleation layers 318, gate stacks 324, contact metal 326, and silicide layers 328. As shown, device 300 includes another of a myriad of shapes that may be utilized for nucleation layers 318. While shown as including squared corners, in some embodiments, nucleation layers 318 may include a combination of squared and rounded corners or no corners at all.

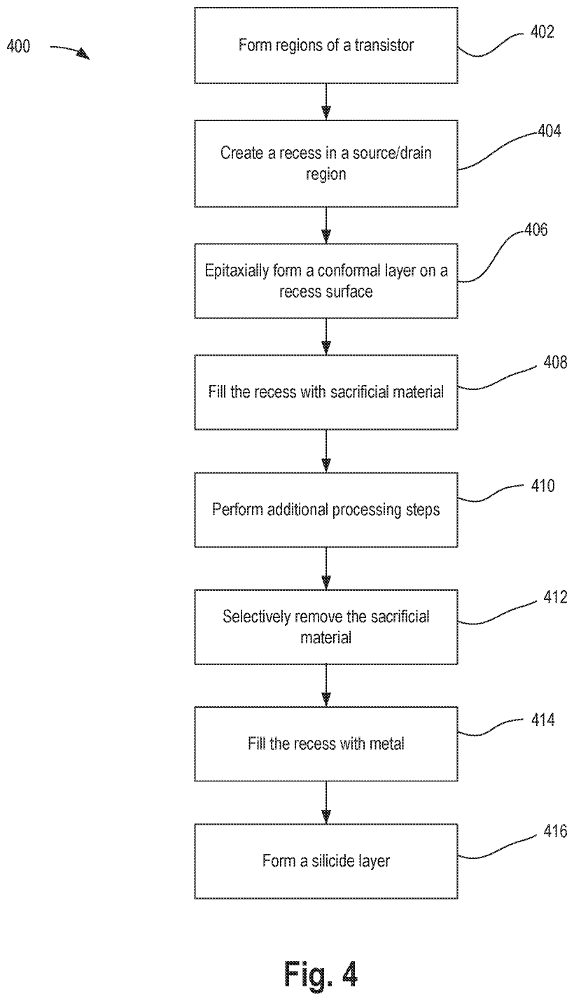

FIG. 4 illustrates a flowchart of a method of forming a semiconductor device with an enhanced metal contact area, in accordance with some embodiments. Although the blocks in the flowchart with reference to FIG. 4 are shown in a particular order, the order of the actions can be modified. Thus, the illustrated embodiments can be performed in a different order, and some actions/blocks may be performed in parallel. Some of the blocks and/or operations listed in FIG. 4 are optional in accordance with certain embodiments. The numbering of the blocks presented is for the sake of clarity and is not intended to prescribe an order of operations in which the various blocks must occur. Additionally, operations from the various flows may be utilized in a variety of combinations.

Method 400 begins with forming (402) regions of a transistor. In some embodiments, source/drain regions, for example 208 and 209, are formed by doping regions of a semiconductor fin. In other embodiments, regions of a transistor may be formed by depositing thin film material. Next, recesses are formed (404) in source/drain regions. In some embodiments, recesses 214 are formed in source 208 and drain 209 by chemical etching. Recesses 214 may be practically any shape or size.

Then, a conformal layer may be epitaxially formed (406) on a recess surface. In some embodiments, nucleation layers 218 may be epitaxially depositing silicon of about 5 nm or less. In some embodiments, nucleation layers 218 are doped with phosphorus or other molecules. Next, the recesses may be filled (408) with a sacrificial material. In some embodiments, sacrificial material 222 may be epitaxially formed silicon germanium or another semiconductor material different from nucleation layers 218.

The method continues with performing (410) additional processing steps. In some embodiments, gate stacks 224 are formed as part of a metal gate replacement and/or other processing steps. Next, sacrificial material is selectively removed (412). In some embodiments, sacrificial material 222 is removed through an isotropic chemical vapor etch that does not react with or remove nucleation layers 218.

Then the source/drain recesses may be filled (414) with metal. In some embodiments, contact metal 226, which may be titanium, cobalt, or another metal, is formed over nucleation layers 218 and fills recesses 214. Finally, a silicide layer may be formed (416) between the contact metal and the nucleation layers. In some embodiments, a titanium contact metal 226 and a silicon nucleation layer 218 are annealed to form a titanium silicon alloy silicide layer 228.

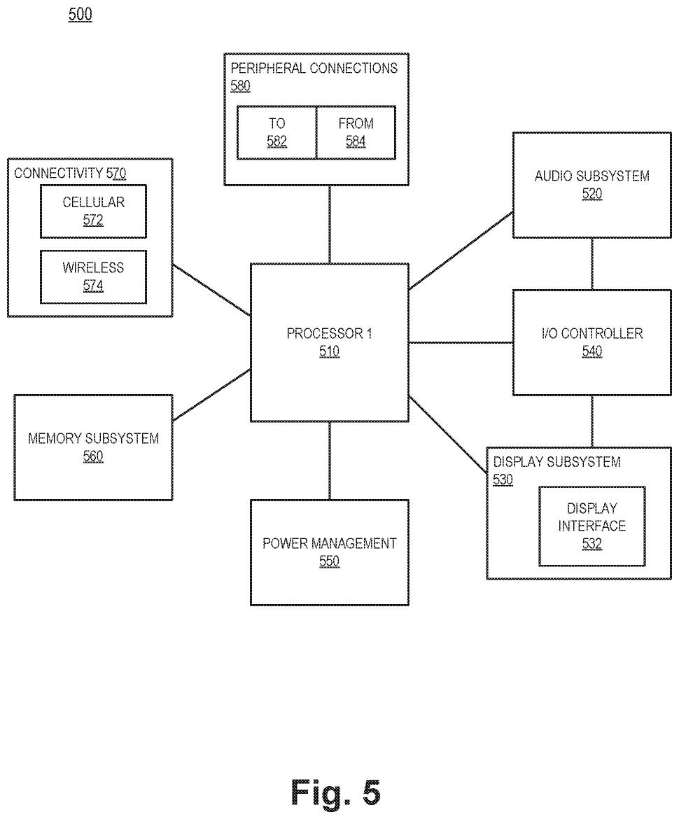

FIG. 5 illustrates a smart device or a computer system or a SoC (System-on-Chip) 500 which includes a semiconductor device with an enhanced metal contact area, according to some embodiments. In some embodiments, computing device 500 represents a mobile computing device, such as a computing tablet, a mobile phone or smart-phone, a wireless-enabled e-reader, or other wireless mobile device. It will be understood that certain components are shown generally, and not all components of such a device are shown in computing device 500. In some embodiments, one or more components of computing device 500, for example processor 510 and/or memory subsystem 560, are include a semiconductor device with an enhanced metal contact area as described above.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors-BJT PNP/NPN, BiCMOS, CMOS, etc., may be used without departing from the scope of the disclosure.

In some embodiments, computing device 500 includes a first processor 510. The various embodiments of the present disclosure may also comprise a network interface within 570 such as a wireless interface so that a system embodiment may be incorporated into a wireless device, for example, cell phone or personal digital assistant.

In one embodiment, processor 510 can include one or more physical devices, such as microprocessors, application processors, microcontrollers, programmable logic devices, or other processing means. The processing operations performed by processor 510 include the execution of an operating platform or operating system on which applications and/or device functions are executed. The processing operations include operations related to I/O (input/output) with a human user or with other devices, operations related to power management, and/or operations related to connecting the computing device 500 to another device. The processing operations may also include operations related to audio I/O and/or display I/O.

In one embodiment, computing device 500 includes audio subsystem 520, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 500, or connected to the computing device 500. In one embodiment, a user interacts with the computing device 500 by providing audio commands that are received and processed by processor 510.

Display subsystem 530 represents hardware (e.g., display devices) and software (e.g., drivers) components that provide a visual and/or tactile display for a user to interact with the computing device 500. Display subsystem 530 includes display interface 532, which includes the particular screen or hardware device used to provide a display to a user. In one embodiment, display interface 532 includes logic separate from processor 510 to perform at least some processing related to the display. In one embodiment, display subsystem 530 includes a touch screen (or touch pad) device that provides both output and input to a user.

I/O controller 540 represents hardware devices and software components related to interaction with a user. I/O controller 540 is operable to manage hardware that is part of audio subsystem 520 and/or display subsystem 530. Additionally, I/O controller 540 illustrates a connection point for additional devices that connect to computing device 500 through which a user might interact with the system. For example, devices that can be attached to the computing device 500 might include microphone devices, speaker or stereo systems, video systems or other display devices, keyboard or keypad devices, or other I/O devices for use with specific applications such as card readers or other devices.

As mentioned above, I/O controller 540 can interact with audio subsystem 520 and/or display subsystem 530. For example, input through a microphone or other audio device can provide input or commands for one or more applications or functions of the computing device 500. Additionally, audio output can be provided instead of, or in addition to display output. In another example, if display subsystem 530 includes a touch screen, the display device also acts as an input device, which can be at least partially managed by I/O controller 540. There can also be additional buttons or switches on the computing device 500 to provide I/O functions managed by I/O controller 540.

In one embodiment, I/O controller 540 manages devices such as accelerometers, cameras, light sensors or other environmental sensors, or other hardware that can be included in the computing device 500. The input can be part of direct user interaction, as well as providing environmental input to the system to influence its operations (such as filtering for noise, adjusting displays for brightness detection, applying a flash for a camera, or other features).

In one embodiment, computing device 500 includes power management 550 that manages battery power usage, charging of the battery, and features related to power saving operation. Memory subsystem 560 includes memory devices for storing information in computing device 500. Memory can include nonvolatile (state does not change if power to the memory device is interrupted) and/or volatile (state is indeterminate if power to the memory device is interrupted) memory devices. Memory subsystem 560 can store application data, user data, music, photos, documents, or other data, as well as system data (whether long-term or temporary) related to the execution of the applications and functions of the computing device 500.

Elements of embodiments are also provided as a machine-readable medium (e.g., memory 560) for storing the computer-executable instructions. The machine-readable medium (e.g., memory 560) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 570 includes hardware devices (e.g., wireless and/or wired connectors and communication hardware) and software components (e.g., drivers, protocol stacks) to enable the computing device 500 to communicate with external devices. The computing device 500 could be separate devices, such as other computing devices, wireless access points or base stations, as well as peripherals such as headsets, printers, or other devices.

Connectivity 570 can include multiple different types of connectivity. To generalize, the computing device 500 is illustrated with cellular connectivity 572 and wireless connectivity 574. Cellular connectivity 572 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 574 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 580 include hardware interfaces and connectors, as well as software components (e.g., drivers, protocol stacks) to make peripheral connections. It will be understood that the computing device 500 could both be a peripheral device (“to” 582) to other computing devices, as well as have peripheral devices (“from” 584) connected to it. The computing device 500 commonly has a “docking” connector to connect to other computing devices for purposes such as managing (e.g., downloading and/or uploading, changing, synchronizing) content on computing device 500. Additionally, a docking connector can allow computing device 500 to connect to certain peripherals that allow the computing device 500 to control content output, for example, to audiovisual or other systems.

In addition to a proprietary docking connector or other proprietary connection hardware, the computing device 500 can make peripheral connections 580 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

In one example, an apparatus is provided comprising: a semiconductor region on a substrate; a gate stack on the semiconductor region; a source region comprising doped semiconductor material on the substrate adjacent a first side of the semiconductor region; a drain region comprising doped semiconductor material on the substrate adjacent a second side of the semiconductor region; a substantially conformal semiconductor layer over a surface of a recess in the source region; and a metal over the conformal layer substantially filling the recess in the source region.

Some embodiments also include a silicide layer between the conformal layer and the metal layer. In some embodiments, the conformal layer comprises phosphorus dopants. In some embodiments, the surface of the recess in the source comprises a curved surface. In some embodiments, the metal comprises titanium. In some embodiments, the conformal layer comprises silicon.

In another example, a NMOS device is provided comprising: a semiconductor region on a substrate; a gate stack on the semiconductor region; a source region of n-doped semiconductor material on the substrate adjacent a first side of the semiconductor region; a drain region of n-doped semiconductor material on the substrate adjacent a second side of the semiconductor region; a first substantially conformal semiconductor layer over a surface of a recess in the source region; a second substantially conformal semiconductor layer over a surface of a recess in the drain region; a first metal over the first conformal layer substantially filling the recess in the source region; and a second metal over the second conformal layer substantially filling the recess in the drain region.

In some embodiments, the semiconductor region, the source region, and the drain region comprise a fin on the substrate. In some embodiments, the first and second conformal layers comprise a thickness of about 5 nm or less. Some embodiments also include silicide layers between the conformal layers and the metal layers. In some embodiments, the first and second metals comprise titanium. In some embodiments, the first and second conformal layers comprise silicon.

In another example, a method is provided comprising: forming a semiconductor region on a substrate; forming a gate stack on the semiconductor region; forming a source region of doped semiconductor material on the substrate adjacent a first side of the semiconductor region; forming a drain region of doped semiconductor material on the substrate adjacent a second side of the semiconductor region; forming a recess through a surface of the source region; epitaxially forming a conformal layer on a recess surface; and forming a metal on the conformal layer substantially filling the recess.

Some embodiments also include: forming a sacrificial material on the conformal layer; and selectively removing the sacrificial material. Some embodiments also include processing the gate stack adjacent the sacrificial material. In some embodiments, the sacrificial material comprises silicon germanium. In some embodiments, the metal comprises titanium. Some embodiments also include forming a silicide layer at a junction of the metal and the conformal layer.

In another example, a method of forming a NMOS device is provided comprising: forming a semiconductor region on a substrate; forming a gate stack on the semiconductor region; forming a source region of n-doped semiconductor material on the substrate adjacent a first side of the semiconductor region; forming a drain region of n-doped semiconductor material on the substrate adjacent a second side of the semiconductor region; forming a recess through a surface of the source region; epitaxially forming a conformal layer on a surface of the source and drain recesses; and forming a metal on the conformal layer substantially filling the source and drain recesses.

In some embodiments, the conformal layer comprises silicon. Some embodiments also include: forming a sacrificial material on the conformal layer substantially filling the recesses; and selectively removing the sacrificial material. Some embodiments also include processing the gate stack adjacent the sacrificial material. Some embodiments also include forming a silicide layer at a junction of the metal and the conformal layer. In some embodiments, the metal comprises titanium. In some embodiments, the conformal layer comprises phosphorus doping.

In another example, a system is provided comprising: a display subsystem; a wireless communication interface; and an integrated circuit device, the integrated circuit device comprising: a semiconductor region on a substrate; a gate stack on the semiconductor region; a source region comprising doped semiconductor material on the substrate adjacent a first side of the semiconductor region; a drain region comprising doped semiconductor material on the substrate adjacent a second side of the semiconductor region; a substantially conformal semiconductor layer over a surface of a recess in the source region; and a metal over the conformal layer substantially filling the recess in the source region.

Some embodiments also include a silicide layer between the conformal layer and the metal layer. In some embodiments, the conformal layer comprises a thickness of about 5 nm or less. In some embodiments, the surface of the recess in the source comprises a curved surface. In some embodiments, the metal comprises titanium. In some embodiments, the conformal layer comprises silicon.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1-50. (canceled)

51. An apparatus comprising:
a semiconductor region over a substrate;
a gate stack over the semiconductor region;
a source region comprising doped semiconductor material over the substrate and adjacent a first side of the semiconductor region;
a drain region comprising doped semiconductor material over the substrate and adjacent a second side of the semiconductor region;
a substantially conformal semiconductor layer over a surface of a recess in the source region; and
a metal over the conformal layer and substantially filing the recess in the source region.

52. The apparatus of claim 51, further comprising a silicide layer comprising a metal and silicon, the silicide layer between the conformal layer and the metal layer.

53. The apparatus of claim 51, wherein the conformal layer comprises phosphorus.

54. The apparatus of claim 51, wherein an interface between the conformal layer and the source region has curvature.

55. The apparatus of claim 51, wherein the metal comprises titanium.

56. The apparatus of claim 51, wherein the conformal layer comprises silicon.

57. An NMOS device comprising:
a source region, a drain region and a semiconductor region therebetween, wherein the source region and the drain region comprise an n-type semiconductor material;
a gate stack over the semiconductor region;
a first substantially conformal semiconductor layer within a recess in the source region;
a second substantially conformal semiconductor layer within a recess in the drain region;
a first metal over the first conformal layer, and within the recess in the source region; and
a second metal over the second conformal layer, and within the recess in the drain region.

58. The NMOS device of claim 57, wherein a fin comprises each of the source region, the drain region and the semiconductor region.

59. The NMOS device of claim 57, wherein the first and second conformal layers have a thickness of no more than 5 nm, and wherein the first and second metals substantially fill the recesses in the source and drain regions.

60. The NMOS device of claim 57, further comprising a silicide layer between the conformal layers and the metal layers, wherein the silicide layer comprises silicon and a metal.

61. The NMOS device of claim 57, wherein the first and second metals comprise titanium.

62. The NMOS device of claim 57, wherein the first and second conformal layers comprise silicon.

63. A method comprising:
forming a gate stack over a semiconductor region;
forming a source region adjacent to a first side of the semiconductor region;
forming a drain region adjacent to a second side of the semiconductor region;
forming a recess into the source region;
epitaxially forming a conformal layer on a recessed surface of the source; and
forming a metal over the conformal layer, the metal substantially filling the recess.

64. The method of claim 63, further comprising:
forming a sacrificial material on the conformal layer; and
selectively removing the sacrificial material.

65. The method of claim 64, further comprising processing the gate stack adjacent the sacrificial material.

66. The method of claim 64, wherein the sacrificial material comprises silicon germanium.

67. The method of claim 64, wherein the metal comprises titanium.

68. The method of claim 64, further comprising forming a silicide layer at a junction of the metal and the conformal layer, wherein the silicide layer comprises silicon and the metal.

69. The method of claim 63, wherein epitaxially forming the conformal layer further comprises growing a semiconductor material comprising phosphorus.

70. The method of claim 69, wherein forming the source region and the drain region comprises forming an n-type semiconductor material.
